(19) United States
(12) Patent Application Publication
(10) Pub. No.: US 2013/0248113 A1
(43) Pub. Date: Sep. 26, 2013

(54) SUBSTANTIALLY NON-OXIDIZING PLASMA TREATMENT DEVICES AND PROCESSES

(71) Applicant: Lam Research Corporation, Fremont, CA (US)

(72) Inventors: Phillip Geissbûhler, Melrose, MA (US); Ivan Berry, Amesbury, MA (US); Armin Huseinovic, Medford, MA (US); Shijian Luo, South Hamilton, MA (US); Aseem Kumar Srivastava, Andover, MA (US); Carlo Waldfried, Middleton, MA (US)

(73) Assignee: Lam Research Corporation, Fremont, CA (US)

(21) Appl. No.: 13/893,062

(22) Filed: May 13, 2013

Related U.S. Application Data
(62) Division of application No. 12/631,117, filed on Dec. 4, 2009.

(51) Int. Cl. H01L 21/67

(52) U.S. Cl. CPC H01L 21/67069
USPC 156/345.27; 156/345.29; 156/345.24

(57) ABSTRACT

Non-oxidizing plasma treatment devices for treating a semiconductor workpiece generally include a substantially non-oxidizing gas source; a plasma generating component in fluid communication with the non-oxidizing gas source; a process chamber in fluid communication with the plasma generating component, and an exhaust conduit centrally located in a bottom wall of the process chamber. In one embodiment, the process chamber is formed of an aluminum alloy containing less than 0.15% copper by weight; In other embodiments, the process chamber includes a coating of a non-copper containing material to prevent formation of copper hydride during processing with substantially non-oxidizing plasma. In still other embodiments, the process chamber walls are configured to be heated during plasma processing. Also disclosed are non-oxidizing plasma processes.

### CROSS-REFERENCE TO RELATED APPLICATIONS

The present disclosure is a divisional of U.S. patent application Ser. No. 12/631,117 filed on Dec. 4, 2009. The entire disclosure of the application referenced above is incorporated herein by reference.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

The present disclosure relates to semiconductor apparatuses and processes, and more particularly, to substantially non-oxidizing plasma mediated processes and plasma treatment devices suitable for treating a semiconductor workpiece.

Recently, much attention has been focused on developing high-k dielectrics with metal gates to enable scaling of devices. As integrated devices become smaller, scaling of the gate dielectric causes increased leakage due to electron tunneling through the thin dielectric layer. A solution to this problem is to implement a gate dielectric with higher dielectric constant (also referred to as “high k”). As used herein, the term “high k” generally refers to a dielectric constant greater than silicon dioxide. The use of high k dielectric layers as gate insulator layers allow thicker layers to be used, with the thicker high k dielectric layer supplying capacitances equal to thinner silicon oxide layers, or with the high k dielectric layer having an equivalent oxide thickness, equal to the thinner silicon dioxide counterpart layer. Therefore the use of high k dielectric layers, for gate insulator layer, will offer reduced leakage when compared to the thicker silicon dioxide gate insulator counterparts. Additionally, most high-k implementations utilize a metal gate electrode to control the threshold voltage and reduce gate electron carrier depletion.

Many different heavy metal oxides and nitrides have been proposed as higher dielectric constant gate materials to replace the standard silicon oxy-nitride gate dielectrics. Included in the list of proposed replacement dielectrics include oxides and nitrides of Barium (Ba), Dysprosium (Dy), Erbium (Er), Gadolinium (Gd), Hafnium (Hf), Lanthanum (La), Scandium (Sc), Tantalum (Ta), Titanium (Ti), and Zirconium (Zr). Metal gate electrodes proposed include pure metals and carbides and nitrides of Ta, Ti, and Tungsten (W). All of these proposed materials (gate dielectric or gate metal) are sensitive to oxidation or oxidizing environments, which can change the stoichiometry of the oxide, consumption of the metal gate, changes to the gate stack work function, changes in the leakage current, and the like.

In fabricating high-k metal gate devices, two integration schemes have emerged: the Gate First scheme and Gate Last scheme. In the so-called Gate First integration scheme, the metal gate and high-k dielectric can be exposed to photoresist strip and wafer clean processes at the source-drain and source-drain extension ion implantation steps. In the so-called Gate Last integration scheme, the metal gate and high-k dielectric can be exposed to the photoresist strip and clean processes at the contact etch steps. In both schemes, the photoresist strip and wafer clean processes that occur subsequent to the high-k/metal gate deposition must take care not to oxidize either the gate materials, change the stoichiometry of the gate dielectric, and/or oxidize the channel underneath the gate dielectric. Ashing refers to a plasma mediated stripping process by which photoresist and post etch residues are stripped or removed from a substrate upon exposure to the plasma. The ashing process generally occurs after an etching or implant process has been performed in which a photoresist material is used as a mask for etching a pattern into the underlying substrate or for selectively implanting ions into the exposed areas of the substrate. The remaining photoresist and any post etch or post implant residues on the wafer after the etch process or implant process is complete must be removed prior to further processing for numerous reasons generally known to those skilled in the art. The ashing step is typically followed by a wet chemical treatment to remove traces of the ashing residue, which can cause device opens or shorts or lead to an increase in device leakage.

Studies have suggested that a significant shift in the work function and/or change to the transistor drive current of a high-k/metal gate transistor can occur when an oxidizing plasma ash process is used. For example, oxidizing plasma discharges are known to convert metal gate electrodes from the as deposited TiN, for example, into TiO₂. Additionally oxidizing plasma discharges can oxidize the silicon conduction channel under the high-k dielectric since most high-k dielectrics are poor diffusion barriers to the oxidizing plasma chemistry and the oxidizing plasmas can change the oxygen content or oxidation state of the high-k dielectric itself. All cases result in degraded transistor performance.

Ideally, the ashing plasma processes should not affect the high-k/metal gate stack or affect the underlying silicon conduction channel and preferentially removes only the photoresist material. In order to minimize damage, substantially non-oxidizing plasma processes have been developed. One such process includes generating plasma from a gas mixture comprising hydrogen and another non-oxidizing gas such as nitrogen, or helium. The mechanism of removal for these less aggressive plasma discharges is significantly different from oxidizing plasmas. The substantially non-oxidizing plasma, such as the plasma formed from nitrogen and hydrogen, does not ash the photoresist in the traditional sense. Rather, it is believed that the hydrogen in the plasma fragments the organic based polymer in the photoresist formulation. These hydrocarbon fragments possess a relatively low vapor pressure as compared to the products obtained after exposure to oxygen containing plasmas, which convert the organic based photoresist into gaseous byproducts such as CO₂, CO, H₂O and the like. The hydrocarbon fragments possessing the lower vapor pressure have a tendency to condense onto relatively cooler surfaces such as the chamber walls, vacuum lines, valves, pumping lines, pumps, and exhaust conduits. The buildup of these ashing materials can lead to short mean-time-between-clean (MTBC) times and frequent rebuild/replacement of vacuum hardware resulting in loss of throughput and increased costs of ownership. Additionally, deposits of the fragmented photoresist material and ashing byproducts within the process chamber that are located above the plane of the substrate can lead to particulate contamination on the substrate, thereby further affecting device yields.

An additional problem with non-oxidizing plasma discharges, such as the hydrogen and nitrogen based plasma discussed above, is the non-uniformity of the plasma exposure especially for prior art apparatuses that have been optimized for oxidizing plasmas. These prior art apparatuses typically include a baffle plate arrangement of some sort (e.g., a dual baffle plate configuration) for uniformly distributing the plasma to the outer edges of the underlying substrate. It has been found that the less aggressive substantially non-oxidizing plasma discharges have fewer reactive species and the dispersal from the center point of the baffle plate to its outer edge can result in hot spots on the wafer, i.e., areas of non-uniformity. Moreover, the excited state species (e.g., H⁺, H*, H₂*) in these substantially non-oxidizing plasmas also can possess relatively short lifetimes and have high recombination rates. While not wanting to be bound by theory, it is believed that the reduction in activity of hydrogen radicals as these species flow to the outer edges of the baffle plate is due to shorter lifetimes of hydrogen radicals than can be supported by the radial distance these species have to travel from the center-fed axial plasma flow to the outer edges of the plenum. Once the hydrogen radicals have recombined into molecular hydrogen or the like, the neutral gas can no longer react with the photoresist. Another reason may be that, in an axial flow reactor design, the photoresist ashing byproducts and spent gas from the central portions of the wafer must flow past the edge of the wafer in order to reach the exhaust conduit, which is typically disposed in a bottom wall of the process chamber. This results in significant dilution of the active hydrogen radicals nearer the edge of the wafer compared to the more central portions and additionally provides for the radicals closer to the edge to deactivate by reacting with the photoresist ashing byproducts that have been removed from the central locations, thereby leading to lower ashing rates at the edge of the wafer.

Still further, it has been discovered that hydrogen-containing substantially non-oxidizing plasmas react with copper to produce copper hydride (CuH) during plasma processing. CuH, like the hydrocarbon fragments discussed above, has a moderately low vapor pressure but still high enough at typical process temperatures to provide a mechanism for transport of copper from the process chamber to the substrate. Because copper is often included as a minor component in the aluminum alloys used to form the process chamber, vacuum components, and the like, the copper present can react with the substantially non-oxidizing plasma and be transported in the form of the intermediate CuH to the semiconductor workpiece by the plasma, thereby contaminating the semiconductor workpiece with copper.

Still further, it has been discovered that many oxides and ceramics degrade and/or devitrify under exposure to substantially non-oxidizing plasmas at elevated temperatures. This degradation/devitrification can lead to particle formation and ultimately failure of the component. An example of this is the plasma containment structure, e.g., plasma tube, used in many plasma sources such as microwave downstream plasma sources.

Accordingly, there remains a need for improved processes and apparatuses for substantially non-oxidizing plasma processing of semiconductor workpieces.

### SUMMARY

Disclosed herein are substantially non-oxidizing plasma mediated processes and plasma treatment devices suitable for treating a semiconductor workpiece. In one embodiment, a plasma treatment device for treating a substrate comprises a gas inlet in fluid communication with a plasma generating component and configured to receive a substantially non-oxidizing gas source, wherein the plasma generating component is configured to generate plasma from the substantially non-oxidizing gas source during operation of the plasma treatment device; a process chamber in fluid communication with the plasma generating component and configured to receive the plasma, wherein the process chamber is formed of a material containing less than 0.15% copper by weight; and an exhaust conduit fluidly connected to the process chamber.

In another embodiment, a plasma treatment device for treating a substrate, comprises a gas inlet in fluid communication with a plasma generating component and configured to receive a substantially non-oxidizing gas source, wherein the plasma generating component is configured to generate plasma from the gas source during operation of the plasma treatment device; a process chamber in fluid communication with the plasma generating component and configured to receive the plasma, wherein one or more interior surfaces of the plasma treatment device comprise a non-copper containing material provided on the interior walls with a thickness effective to prevent formation of a copper hydride species upon exposure to the plasma; and an exhaust conduit fluidly connected to the process chamber.

In still another embodiment, a plasma treatment device for treating a semiconductor workpiece comprises a gas inlet in fluid communication with a plasma generating component and configured to receive a substantially non-oxidizing gas source, wherein the plasma generating component is configured to generate plasma from the substantially non-oxidizing gas source during operation of the plasma treatment device; and a process chamber in fluid communication with the plasma generating component and configured to receive the plasma, wherein interior surfaces of the plasma treatment device are configured to be heated to a sufficient temperature to prevent photoresist and reaction byproduct buildup on the interior surfaces.

A substantially non-oxidizing plasma process for removing photoresist from a substrate within a process chamber comprises exciting a gas mixture comprising a substantially non-oxidizing gas to form reactive plasma species wherein the substantially non-oxidizing gas comprises at least one gas selected from the group consisting of H₂, NH₃, N₂H₄, H₂S, CH₄, C₂H₆, C₃H₈, HF, H₂O, HCl, HBr, HCN, CO, N₂O, and combinations thereof; exposing the substrate to the reactive plasma species, wherein the process chamber is formed of an aluminum metal alloy having a copper content to less than or equal to 0.15%; by weight so as to inhibit formation of copper hydride from interior surfaces of the process chamber exposed to the reactive plasma species; and selectively reacting photoresist on a semiconductor workpiece with the reactive plasma species to remove the photoresist from the substrate and form volatile photoresist and reaction byproducts.

In another embodiment, a substantially non-oxidizing plasma process for removing photoresist from a substrate within a process chamber comprises exciting a gas mixture comprising a substantially non-oxidizing gas to form reactive plasma species wherein the substantially non-oxidizing gas comprises at least one gas selected from the group consisting of H₂, NH₃, N₂H₄, H₂S, CH₄, C₂H₆, C₃H₈, HF, H₂O, HCl, HBr, HCN, CO, N₂O, and combinations thereof; and selectively reacting photoresist on a semiconductor workpiece with the reactive plasma species to remove the photoresist from the substrate and form volatile photoresist and reaction byproducts, wherein surfaces exposed to the substantially non-oxidizing plasma contain a copper content sufficiently low to prevent copper contamination of the semiconductor workpiece to a level of less than or equal to 2×10¹⁰ copper atoms per cm².

The above described and other features are exemplified by the following figures and detailed description.

### BRIEF DESCRIPTION OF THE DRAWINGS

Referring to the exemplary drawings wherein like elements are numbered alike in the several Figures:

FIG. 1 is a cross sectional view of a plasma ashing apparatus that includes a wide area plasma source for generating a substantially non-oxidizing plasma and an oxygen plasma abatement system located downstream of the plasma processing chamber;

FIG. 2 is an exploded view of an exemplary wide area plasma source;

FIG. 3 is a cross sectional view of a downstream plasma ashing apparatus that includes a narrow area plasma source for generating a substantially non-oxidizing plasma and an oxygen plasma abatement system located downstream of the plasma processing chamber;

FIG. 4 is a cross sectional view of a process chamber configured to receive plasma from a narrow area plasma source in accordance with an embodiment of the invention;

FIG. 5 graphically illustrates vapor pressure of copper hydride as a function of temperature;

FIG. 6 graphically illustrates pressure of oxygen in a process chamber at a pressure of 1 torr as a function of process gas flow into the process chamber when oxygen is injected into an oxygen plasma abatement system located downstream of the process chamber;

FIG. 7 schematically represents gas flow configuration in accordance with one embodiment of the present invention that is suitable for use with a substantially non-oxidizing plasma apparatus;

FIG. 8 graphically illustrates detected copper levels on silicon substrates processed in various process chambers with a hydrogen-containing substantially non-oxidizing plasma, wherein the interior surfaces are coated and/or formed of different materials;

FIG. 9 graphically illustrates the amount of oxidation of TiN as a function of oxygen contained in an O₂/NH₃ plasma gas mixture, wherein the TiN was exposed to plasma generated from the plasma gas mixture.

FIG. 10 graphically illustrates the amount of TiN loss as a result of oxidation as a function of the amount of oxygen contained in a hydrogen bearing plasma gas mixture, wherein the TiN was exposed to plasma generated from the plasma gas mixture.

### DETAILED DESCRIPTION

Disclosed herein are processes and plasma treatment devices (i.e., apparatuses) for substantially non-oxidizing plasma processing a semiconductor workpiece so as to remove organic matter therefrom, e.g., photoresist, photoresist ashing byproducts, post etch residues, and the like. Although reference herein will be made specifically to devices and substantially non-oxidizing plasma processes for ashing photoresist and ashing byproducts from semiconductor workpieces that may include a high-k dielectric material and/or metal gates, the invention is not intended to be limited as such. With respect to photoresist ashing, the processes and devices described herein can effectively prevent or eliminate hydrocarbon buildup within the process chamber as well as in the exhaust gas lines that may occur as a function of the substantially non-oxidizing plasma to remove the photoresist material. Moreover, the devices and processes provide improved plasma uniformity and a reduction in copper contamination. The substantially non-oxidizing plasma processes are generally optimized to oxidize exposed materials to less than about 0.3 nanometers (nm) in depth during the photoresist ashing process.

The substantially non-oxidizing plasmas for ashing photoresist are typically hydrogen-containing gas mixtures but other non-hydrogen-containing gases have been shown to also be substantially non-oxidizing, including but not limited to N₂O and CO. Exemplary substantially non-oxidizing plasmas are disclosed in U.S. Patent Publication No. 2009/0277871A1 entitled, Plasma Mediated Ashing Processes That Include Formation of a Protection Layer Before and/or During the Plasma Mediated Ashing Process, and in U.S. patent application Ser. No. 12/275,394 entitled. Front End of Line Plasma Mediated Ashing Processes and Apparatus, both of which are incorporated herein by reference in their entireties. The particular components of the plasma gas mixture are selected by their ability to form a gas and plasma at plasma forming conditions. The gas mixture selected is substantially free from components that generate reactive oxygen species in excess of non-oxidizing reactive species at plasma forming conditions. The gas mixture may include reactive gases such as a hydrogen-bearing gas, a nitrogen-bearing gas, a fluorine-bearing gas, a chlorine-bearing gas, a bromine-bearing gas, and mixtures thereof. The gas mixture may further comprise an inert gas such as argon, helium, neon, and the like. The plasma generated from these gas mixtures primarily reacts with carbon and other atoms within the photoresist, polymers, and residues to form somewhat volatile and/or sublimable compounds and/or rinse-removable compounds. The term “substantially” as used herein generally refers to plasma gas mixtures that form plasmas wherein the non-oxidizing reactant concentration greatly exceeds the oxidizing reactants. By way of example, a substantially non-oxidizing plasma gas mixture is a mixture of NH₃ and O₂, wherein the volumetric concentration of O₂ is less than 30%. In many instances, it may be beneficial to add a small amount of oxygen gas to the substantially non-oxidizing plasma to increase ashing rate as well as to inhibit copper hydride formation in process chambers formed of an aluminum alloy having a small percentage of copper within the alloy composition, which will be discussed in greater detail below.

Substrate oxidation for certain substantially non-oxidizing plasma chemistries are very sensitive to the amount of background oxygen present. An example is when the substantially non-oxidizing plasma chemistry is forming gas (e.g., a mixture of 5% by volume hydrogen gas (H₂) in nitrogen gas (N₂)) and silicon oxidation is of concern. In this case, small vacuum leaks within the device can introduce sufficient amounts of oxygen to render the process oxidizing. In such cases, it is beneficial to monitor the optical emission spectrum emanating from the generated plasma. Spectral emission lines for excited state O (e.g., 777 nm, 845 nm, and/or 927 nm) can be monitored and the process terminated or a warning signal provided should the intensity of these emission lines exceed or drop below a pre-determined value or range. Alternatively, or in combination, molecular emission lines from OH (307 nm) or CO (293 nm, 303 nm, 314 nm, 484 nm, and/or 520 nm) can be monitored. The device may include a feedback loop to provide the process termination and/or warning signals, which is well within the skill of those in the art. In this manner, an optical detector coupled to the process chamber can be used to detect vacuum leaks and the like.

Hydrogen-bearing gases suitable for use in the substantially non-oxidizing plasma process include those compounds that contain hydrogen. The hydrogen-bearing gases include hydrocarbons, hydrofluorocarbons, hydrogen gas, ammonia, hydrides, or mixtures thereof. Preferred hydrogen-bearing gases exist in a gaseous state at plasma forming conditions and release hydrogen to form reactive hydrogen such as atomic hydrogen and excited state molecular hydrogen species under plasma forming conditions. The hydrocarbons or hydrofluorocarbons are generally unsubstituted or may be partially substituted with a halogen such as bromine, chlorine or fluorine. Examples of hydrogen-bearing hydrocarbon gases include methane, ethane and propane.

Hydrogen-bearing gases may be composed of mixtures of a hydrogen gas and a noble gas or nitrogen. Examples of noble gases suitable for use in the process include a gas in Group VIII of the periodic table such as argon, neon, helium, nitrogen, and the like. Particularly preferable for use in the present invention is a gas mixture that includes a hydrogen bearing gas and a nitrogen bearing gas.

Halogen-bearing compounds in the plasma are less than about 10 percent of the total volume of the plasma gas mixture to maximize selectivity. It has been found that when the fluorine compounds, for example, are greater than about 10 percent by volume, polymerization of the photoresist byproducts can occur making the polymerized photoresist more difficult to remove. Preferred halogen compounds include those compounds that generate halogen reactive species when excited by the plasma. Preferably, the halogen compound is a gas at plasma forming conditions and is selected from the group consisting of a compound having the general formula CₓH_{y}A_{z}, wherein A represents a halogen such as F, Cl, Br or I, x ranges from 1 to 4, y ranges from 0 to 9 and z ranges from 1 to 10, HF, F₂HCl, HBr, Cl₂, Br₂, and SF₆. Other halogen bearing compounds that do not generate reactive substantial amounts of oxygen species will be apparent to those skilled in the art. More preferably, the halogen-bearing compound is CF₄, C₂F₆, CHF₃, CH₂F₂, CH₃F or mixtures thereof.

To prevent the reduction of metal nitrides or silicides, a reduction suppression gas containing a nitrogen bearing gas may be added to the substantially non-oxidizing gas or gas mixture. Preferably, the nitrogen bearing gas is N₂, NH₃, NO, NO₂, and/or N₂O. In the case of NH₃, this can also function as the source for both the nitrogen bearing gas and the hydrogen bearing substantially non-oxidizing gas.

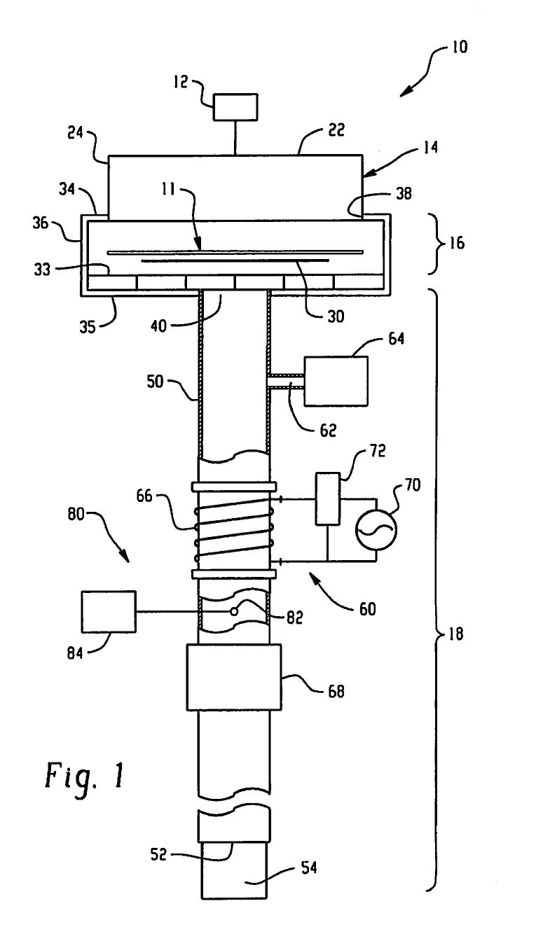

Turning now to FIG. 1, there is shown a plasma apparatus 10 (i.e., plasma treatment device) configured for substantially non-oxidizing plasma processing organic based materials such as photoresist, sidewall deposits, post etch residues, and the like for removal thereof from substrates 11 (i.e., semiconductor workpieces) that include high-k dielectric materials, metal gate materials or other materials sensitive to oxidation. The plasma apparatus 10 generally comprises a substantially non-oxidizing gas delivery component 12, a plasma-generating component 14, a processing chamber 16, and an exhaust assembly 18. It is to be understood that the plasma apparatus has been simplified to illustrate only those components that are relevant to an understanding of the present disclosure. Those of ordinary skill in the art will recognize that other components may be required to produce an operational plasma ashing apparatus 10. However, because such components are well known in the art, and because they do not further aid in the understanding of the present disclosure, a discussion of such components is not provided. The apparatus 10 overcomes many of the problems noted in the prior art as it relates to processing substrates with substantially non-oxidizing plasma discharges, and in particular, plasma uniformity, hydrocarbon condensation, and copper metal contamination, among others.

In one embodiment, the gas delivery component 12 provides the above mentioned gas mixture to the plasma generating component 14, which in the present figure is configured as a wide area plasma source. In practice, the plasma source can be either a narrow area plasma source or a wide area plasma source. As used herein, the term “wide area” generally defines a plasma generating component that is configured to generate plasma over relatively large area that is about the size of the underlying semiconductor workpiece. Advantageously, the wide area plasma source uniformly distributes the reactive species over the entire semiconductor workpiece without the need for a plasma and/or gas distribution component, thereby minimizing recombination of the excited species. Suitable wide area plasma sources include, without limitation, wide area radio frequency plasma sources, inductively coupled plasma sources, capacitively coupled plasma sources, electron cyclotron resonance sources, and the like. An exemplary wide area plasma source apparatus is disclosed in U.S. Patent Publication No. 200810138992A1, incorporated herein by reference in its entirety. In contrast, a “narrow area” plasma source is generally defined as a plasma generating component configured to generate plasma over an area less than a width of the substrate being processed. Typically, narrow plasma area plasma sources further employ a plasma and/or gas distribution component such as a baffle plate assembly to uniformly distribute plasma onto the entire surface of the substrate.

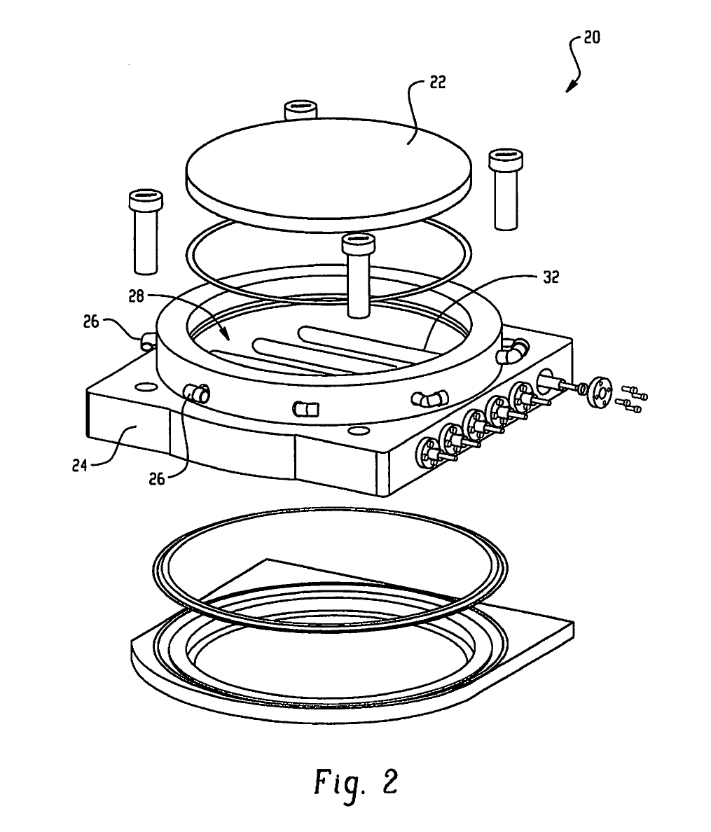

A more detailed schematic of the exemplary wide area plasma source 14 shown in FIG. 1 is a wide area radiofrequency plasma source 20 as depicted in FIG. 2, which can be coupled to an opening 38 in a top wall 34 of the process chamber 16. As shown more clearly in FIG. 2, the exemplary wide area plasma source 20 generally includes a top wall 22, and sidewalls 24 extending from the top wall 22. One or more gas inlets 26 are in fluid communication with an interior region of the plasma source 20 and are positioned to inject gases above an underlying antenna array system 28. The gas inlets 26 can be in the sidewall as shown or top wall (not shown) as may be desired for different apparatus configurations.

The antenna array system 28 includes a planar array of single antenna conductors 32 coupled together and in electrical communication with a power source (not shown). Each conductor 32 is substantially parallel to an adjacent conductor. The particular configuration of the various conductors that define the antenna array is not intended to be limited. The illustrated antenna array system 28 in the present example extends from one sidewall to an opposing sidewall to form a grating and is positioned intermediate the gas inlets 26 and the underlying wafer pedestal 30. During operation, the antenna array system 28 provides excitation energy over a wide area for plasma generation of gases flowing through the gas inlets 26 within the process chamber 16. Optionally, the wide area plasma source may include a baffle plate (not shown) configured to remove charged species from the plasma prior to plasma exposure of the semiconductor workpiece.

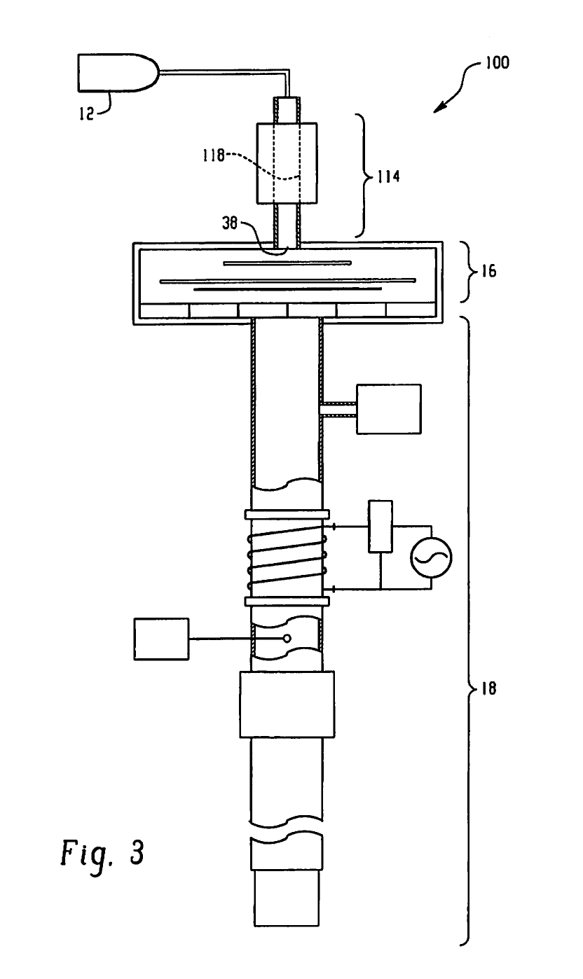

FIG. 3. depicts a plasma apparatus 100 that includes a plasma generating component generally designated by reference numeral 114 that is a narrow area plasma source. The narrow area plasma generating component includes a plasma tube 118 (i.e., a plasma containment device) coupled to an energy source (not shown) such as microwave energy and/or radio frequency energy for exciting gases flowing therethrough. The plasma tube 118 may be actively temperature controlled such as by flowing fluid in a space defined by the plasma tube and an outer envelope (not shown) circumscribing the plasma tube. Exemplary plasma apparatuses including the narrow area plasma generating component include axial flow downstream plasma ashers such as those described in U.S. Pat. Nos. 7,449,416, and 6,897,615, incorporated herein by reference in their entireties.

Referring back to FIG. 1, the process chamber 16 is typically installed within the plasma ashing apparatuses 10, 100 intermediate the exhaust assembly 18 (below) and the plasma-generating component 14, 114 (above) as is generally shown in FIGS. 1 and 3. The process chamber 16 includes a bottom wall 35, a top wall 34 and sidewalls 36 extending from the bottom wall 35 to the top wall 34. The top wall 34 includes an opening 38 for introduction of the plasma or gases for forming the plasma into process chamber 16. Depending on the type of plasma generating component (e.g., 14 or 114), the opening 38 can be relatively small (see FIG. 3) to accommodate narrow area plasma sources such as is commonly employed in downstream plasma generators or relatively large (see FIG. 1) to accommodate seating and/or integration of wide area plasma generators. Openings may also be disposed in the various walls that define the process chamber 16 and/or the plasma generating component 14 such as, for example, an optical port for monitoring endpoint detection in an in situ chamber cleaning process, a mass spectrometer inlet for analyzing gaseous species evolved during processing, or the like. Additionally, the process chamber 16 includes an exhaust opening 40. In some embodiments, the exhaust opening 40 may be centrally disposed in the bottom wall 35. In other embodiments specific to narrow area plasma generators 114 of FIG. 3, the exhaust opening 40 is coaxial with an opening 38 of the plasma tube 118 such as is commonly employed in narrow area plasma sources.

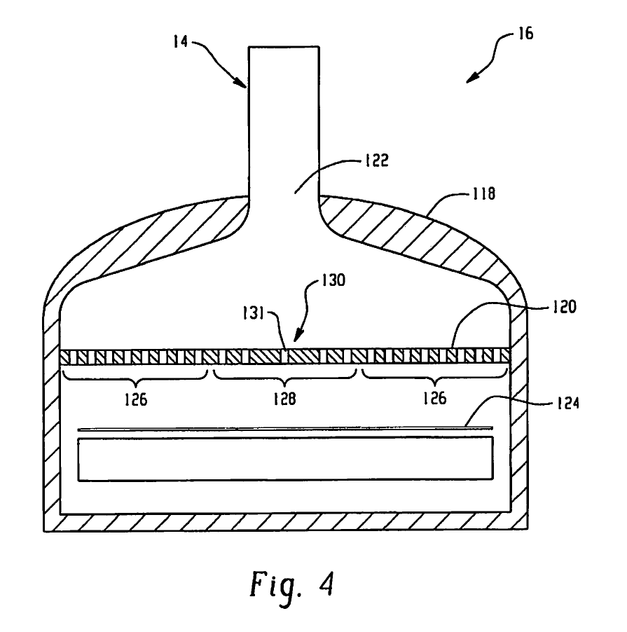

In an alternative embodiment specific to narrow area plasma sources 114, the process chamber 16 is configured to have a domed top wall 118 and a single baffle plate 120 as shown in FIG. 4. The domed top wall 118 is dimensioned such that the reactive species travel about the same path length from the plasma tube opening 122 to all points on the workpiece surface 124. The slight differences in path length can be compensated for by use of the single baffle plate 120, which is configured to have an aperture density at the outer regions 126 to be greater than those in the inner regions 128. Moreover, it is generally preferred that the inner region 128 of single baffle plate 120 is configured to have a substantially apertureless central portion 130 having a single aperture 131 at the centermost point of the baffle plate, wherein the substantially apertureless central portion 130 is at about the same diameter as the plasma tube opening 122. The centermost aperture 131 is configured to allow sufficient flow of the active species to reach the central region of the workpiece. The substantially-apertureless central portion 130 has the function of eliminating the high axial gas velocity exiting the plasma generating component and accelerating the gas/plasma species in a radial direction in order to achieve proper operation of the plenum formed between the baffle plate 120 and the domed wall 118 (i.e., lid) of the process chamber. The plasma is then distributed into the process chamber cavity via apertures in the baffle plate. The combination of the domed wall 118 and the single baffle plate 120 provide uniform distribution of the reactive species generated in the substantially non-oxidizing plasma. Advantageously, the single baffle plate 120 including the substantially-apertureless central portion 130 can be fabricated from optically opaque materials such that any ultraviolet light created in the plasma generation region of source 114 does not travel directly to the corresponding central region of the underlying semiconductor workpiece, thereby preventing interface trapped charges that can deleteriously harm the manufactured device within the exposed region.

It has also been discovered that increased uniformity of ashing can be achieved distally from the centerpoint of the baffle plate to the outer edges by increasing the aperture density of the baffle plate. For example, by increasing the aperture density from the centermost point to the outer edges or by increasing the size of the apertures from the centermost point of the baffle plate to the outer edges, by including the substantially-apertureless portion as described above, or by a combination of one or more of the foregoing baffle plate configurations, can increase reactivity and improve plasma uniformity at the substrate.

Alternatively, the process chamber 16 configured for use with the narrow area plasma generating component is free of a baffle plate and domed top wall, wherein the semiconductor workpiece is seated on a movable stage in the x-y directions. In this manner, the plasma source is scanned across the workpiece surface in the x and y directions.

The process chamber 16 further includes a wafer pedestal 30 (as shown in FIG. 1), e.g., chuck, which can function as a heated platen for heating the semiconductor workpiece during plasma processing. Optionally, the semiconductor workpiece 11 can be heated using a lamp array 33 underlying the substrate as shown in FIG. 1.

The operating pressures within the process chamber 16 are preferably about 100 millitorr to about 10 torr, with about 200 millitorr to about 2 torr more preferred, and with about 500 millitorr to about 1.5 torr even more preferred.

In one embodiment to substantially prevent hydrocarbon buildup, surfaces that are exposed to the volatile photoresist, ashing byproducts, and the like during processing are heated. For example, the process chamber walls, e.g., bottom wall 35, top wall 34, and sidewalls 36, can be heated during substantially non-oxidizing plasma processing. In one embodiment, the process chamber walls are heated to greater than 60° C. to substantially prevent hydrocarbon buildup, and in other embodiments, the process chamber walls are heated to greater than 100° C. At chamber wall temperatures greater than 100° C., hydrocarbon buildup within the interior of the process chamber 16 was found to be completely eliminated. Heating of the process chamber walls can be caused by resistive heating, lamp heating, induction heating, or the like, the manner of which is well within the skill of those in the art. Optionally, the process chamber walls may be thermally insulated to minimize heat loss and increase thermal uniformity of the chamber's internal walls. Insulating the walls of the process chamber 16 can increase thermal uniformity of the chamber's internal walls, provide protection of sensitive components, and increase efficiency by lowering power usage, among others. In another embodiment, the vacuum lines, e.g., exhaust conduit 50, are heated in a similar manner. In apparatuses that include an after burner assembly 60 (shown in FIG. 1 and discussed in greater detail below), the portion of the exhaust conduit 50 in fluid communication with the process chamber and immediately prior to the afterburner assembly 60 is preferentially heated. Heating the process chamber walls and the portion of the exhaust conduit 50 substantially prevents or eliminates hydrocarbon buildup. Still further, in some applications, the process chamber may be cooled in the event the process chamber surfaces are too hot for a given process. In these embodiments, the process chamber may further include an active temperature control system for regulating temperature of the process chamber walls. For cooling, the process chamber may be configured with fluid passages, and the like.

Prior art process chambers including the wafer support i.e., chuck, are typically fabricated from an aluminum alloy, such as type 6061, which includes copper in an amount greater than 0.15% by weight of the alloy. As noted in the background section, hydrogen-containing non-oxidizing plasmas can react during plasma processing with any exposed copper source within the process chamber to form copper hydride. The copper within the copper hydride can then be transported within the plasma to the semiconductor workpiece, thereby contaminating semiconductor workpiece and likely affecting the electrical properties associated of any integrated circuit formed from the contaminated semiconductor workpiece. To prevent copper contamination, an aluminum alloy having a copper content less than 0.15% by weight of the alloy is used to fabricate the process chamber 16 (e.g., top wall, bottom wall, sidewalls, wafer pedestal, and the like). In other embodiments, the aluminum alloy has a copper content less than 0.10% by weight of the alloy, and in still other embodiments, the aluminum alloy is selected to have a copper content of less than 0.07% by weight of the alloy. For example, Type 5083 aluminum alloy can be used to fabricate the process chamber 16 or wafer pedestal 30, which has a copper content less than 0.1% by weight depending on the manufacturer source. The use of aluminum alloys having the lower copper content substantially reduces formation of copper hydride during plasma processing as less copper is available.

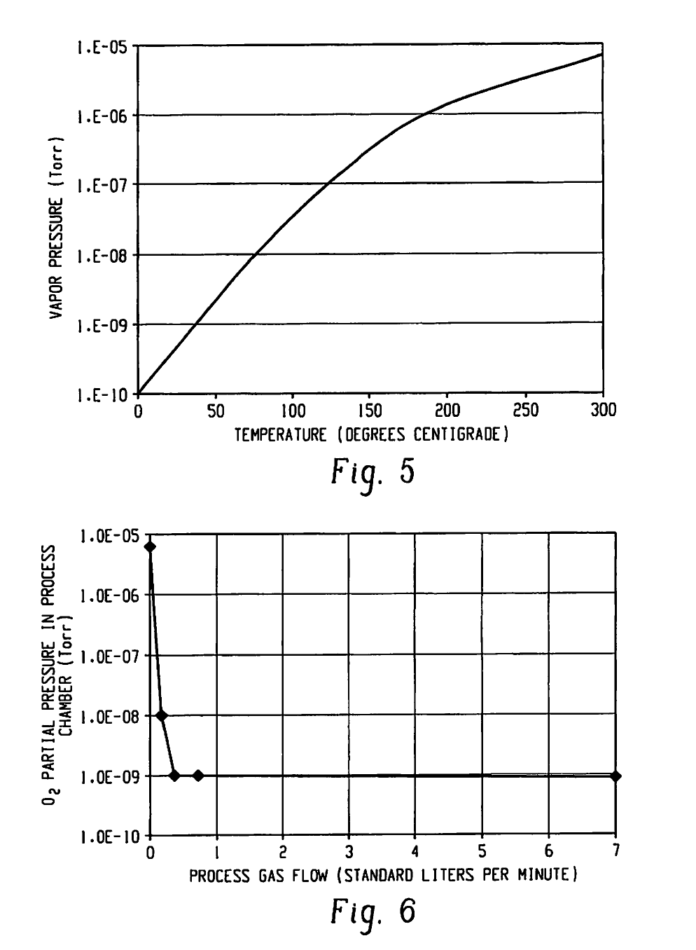

It has also been discovered that the temperature within the process chamber 16 affects the reaction of the reactive species generated from the substantially non-oxidizing plasma process with any copper present the aluminum alloy. As shown in FIG. 5, the vapor pressure of CuH is strongly dependent on temperature. At relatively low temperatures of less than 50° C., the use of an aluminum alloy having a copper content less than 0.15% by weight effectively and substantially prevents formation of copper hydride during non-oxidizing plasma processing. At temperatures greater than 50° C., copper hydride formation can occur with higher vapor pressures depending on the temperature and deleteriously contaminate the semiconductor workpiece during plasma processing in the manner as previously described. To substantially prevent copper hydride formation at an elevated temperature greater than 50° C., the aluminum alloy can be coated with a non-copper containing material. In one embodiment, the aluminum alloy is subjected to an anodization process to form an anodized surface, which has been found to reduce the copper concentration at the surface. Anodization substantially reduces copper hydride formation at plasma processing temperatures of 50° C. to 200° C. A suitable anodization process is MIL-A-8625, Type III, Class I, incorporated herein by reference in its entirety, which uses no dyes and no sealants. Typical anodization thickness using this process is about 0.0020 to about 0.0025 inches.

Alternatively, the aluminum alloy surfaces can be coated with a non-copper containing material to provide protection at temperatures greater than 100° C. Optionally, the aluminum alloy can be anodized prior to deposition of the non-copper containing coating. Suitable materials include, without limitation, silicon carbide (SiC), silicon oxynitride (SiON), tantalum (Ta), tantalum nitride (TaN), titanium nitride (TiN), silicon oxycarbide (SiOC), aluminum oxide (Al₂O₃), pure aluminum, silicon nitride, and the like. By way of example, Table I provides the thickness required for various materials to keep the surface copper concentration at 1/1000^{th} of the copper concentration in the aluminum alloy after 1 year at the given temperature. As shown, diffusion of copper in aluminum is relatively high as evidenced by the relatively large coating thickness whereas minimal diffusion, which translates to smaller coating thicknesses, was observed with materials such as SiC, SON, Ta, TaN, and Ti. It is also noted that the manner in which the non-copper coating material is deposited can affect copper diffusivity. For example, thermally grown silicon oxide is much more effective at lowering copper diffusivity than silicon oxide deposited by a plasma enhanced chemical vapor deposition process (PECVD). In one embodiment, the non-copper containing material is SiON having a thickness of 6 microns or greater, which would maintain the surface copper concentration of 1/1000^{th} of the copper concentration in the aluminum alloy after more than 1 year at 300° C. In another embodiment, the non-copper containing coating material is Al₂O₃ having a thickness of about 2 microns or greater. In another embodiment the non-copper containing coating material is SiC having a thickness of about 1 micron or greater.

TABLE I

| | THICKNESS | THICKNESS |
|---|---|---|
| MATERIAL | at 275° C. (μm) | at 300° C. (μm) |
| Aluminum | 56 | 106 |
| PECVD Al₂O₃ | 4 | 7 |
| Silicon | 1.8 × 10⁵ | 2.6 × 10⁵ |
| SiC | <1 | ~1 |
| Thermal SiO₂ | 1.5 | 2.4 |
| PECVD SiO₂ | 28 | 48 |
| PECVD SiON | 3 | 6 |
| Ta | 7 | 7 |
| TaN | 2 × 10⁻⁶ | 1 × 10⁻⁵ |
| Ta₂N | 3 | 4 |
| Ti | 1 | 3 |

In still another embodiment, a sleeve can be formed of a non-copper containing material such as those described above. The sleeve can be configured to the contour of the chamber sidewalls 24 such that the non-copper containing sleeve is exposed to the plasma instead of the aluminum alloy sidewalls.

Alternatively or in combination with the coated and/or anodized surfaces and/or sleeve as described above, trace gases can be added to the gas mixture to substantially prevent or prevent copper hydride formation. Table II below provides the bond strength data for various copper compounds relative to copper hydride at 275° C. and 300° C. Inhibition of CuH formation can be expected by addition of gaseous species that form bond strengths at about the bond strength for CuH or higher. As such, in some instances it may be beneficial to form these compounds with copper by addition of gases such as, without limitation, O₂, N₂O, NH₃, CH₄, CF₄, C₂F₆, SF₆, H₂S, Cl₂, F₂, CHF₃, CH₂F₂, CH₃F, HF, HCl, CO, CO₂, HCN, C₂H₆, C₃H₈, mixtures thereof, and the like into the plasma and in an amount effective to form the respective higher bond strength copper compound. The amount of gas added to effect inhibition is generally less than 3 vol % of the total gas flow for some embodiments; and in other embodiments, the amount of gas is less than 2 vol % of the total gas flow. For example, addition of 1 vol % O₂ to a 5 vol % hydrogen in helium gas mixture used to form the substantially non-oxidizing plasma was found to reduce the CuH formation in the process chamber by as much as fifteen times. In still other embodiments, the surfaces exposed to the substantially non-oxidizing plasma contain a copper content sufficiently low to prevent copper contamination of the semiconductor workpiece to a level of less than or equal to 2×10¹⁰ copper atoms per cm².

TABLE II

| COPPER | BOND ENERGY |
|---|---|
| COMPOUND | (kJ/Mol) |
| Cu—H | 277 |
| Cu—O | 270 |
| Cu—S | 276 |
| Cu—Cl | 378 |
| Cu—F | 413 |
| Cu—CO | 150 |
| Cu—CN | 320 |

Referring again to FIG. 1, the exhaust assembly component 18 is coupled to the process chamber 16 and includes the exhaust conduit 50 in fluid communication with an interior region of the process chamber 16. It should be noted that the plasma generating component 14 or 114 is independent of the exhaust assembly component 18. That is, the exhaust assembly component as described below is applicable to any type of plasma generating component. The exhaust conduit 50 is fluidly attached to opening 40 in the bottom plate 35 of the process chamber 16. In one embodiment, the exhaust conduit 50 is fabricated from quartz or sapphire coated quartz, aluminum or stainless steel. For narrow area and wide area plasma sources, the minimum diameter of the exhaust conduit 50 (and opening 40) is preferably at least about 2 inches but not greater than about 6 inches for a 300 mm ashing apparatus (about a 1.5 inch diameter but not greater than 5 inches greater is preferred for a 200 mm plasma ashing apparatus).

In one embodiment, the exhaust conduit further includes an afterburner assembly 60. In this embodiment, the inside diameter of the exhaust conduit is configured to be large enough to maintain the operating pressure in the process chamber 16 and a pressure differential effective to prevent oxygen injected into the afterburner assembly 60 from diffusing back into the process chamber 16 via conduit 50.

The outlet 52 of the exhaust conduit 50 is preferably connected to vacuum system 54. An afterburner assembly 60 is in operative communication with the exhaust conduit 50. For plasma apparatuses equipped with the afterburner assembly 60, a gas inlet 62 and gas source 64 are in fluid communication with the exhaust conduit 50 and are positioned upstream from the afterburner assembly 60. The afterburner assembly 60 is employed to generate a plasma discharge within the exhaust conduit 50 so as to volatilize any photoresist material and plasma ashing byproducts discharged from the process chamber 16 before such photoresist and byproducts deposit on downstream vacuum components. As will be described in greater detail below, the gas source 64 is preferably a reactant gas such as oxygen or a combination of gases including oxygen containing gases or halogen containing gases or combinations thereof. In this manner, effluent from the process chamber 16 into the exhaust conduit 50 is mixed with the reactant gas source e.g., oxygen, and a plasma is formed within the exhaust conduit from the mixture by the afterburner assembly 60, the manner of which is described below. It is preferred that the reactant gas is introduced to the afterburner assembly immediately above the assembly and is downstream from the exhaust opening 40 of the process chamber 16. Entry of the reactant gas into the process chamber 16 can deleteriously affect the gate stack in the manner previously described. The hardware and process for generating plasma in the exhaust conduit is preferably adapted to prevent the reactant gas from traveling upstream, i.e., back into the process chamber. FIG. 6 graphically depicts the gas flow necessary at a process chamber pressure of 1 torr to prevent of the reactant gas source (O₂ in this example) from back streaming into the process chamber. The data indicates that a flow greater than 1 standard liters per minute (SLM) must be employed to maintain the reactant gas pressure in the process chamber at background levels.

In one embodiment, the afterburner assembly 60 preferably comprises an RF coil 66 wrapped about an exterior of an insulated exhaust pipe connected to the exhaust conduit 50 to inductively excite a gas mixture flowing through the exhaust conduit. It should be noted that the portion of the exhaust conduit 50 coupled to the afterburner RF coil 66 can be formed of quartz or a non-conductive dielectric material that has a low loss when immersed in the RF field whereas the remaining sections of the exhaust conduit 50 can be formed of a metal. Although reference is made to inductively coupling the gas mixture with RF power to form the plasma, other means could be employed in an effective manner such as by capacitive excitation or the like. Additionally, other frequencies in the ISM band including microwaves may be used to excite the afterburner plasma. The reactant gas is preferably introduced at inlet 62 upstream from the afterburner assembly 60. A throttle valve 68, foreline valve (not shown), vacuum pump 54, and other vacuum processing lines are disposed downstream from the afterburner assembly 60.

The RF coils 66 are connected to a suitable RF generator or power supply 70. The power supply frequency may vary, typically ranging from 400 KHz to the preferred value of 13.56 MHz at less than 1,000 watts (W), but may also be at higher frequencies and higher power. More preferably, an RF power of about 300 W to about 600 W is employed to inductively couple reactive species containing plasma in the exhaust conduit 50, which causes the organic matter contained therein to combust. As a result, deposition of photoresist material and other organic byproducts downstream from the process chamber is prevented and/or removed.

The RF connections are typically made through an RF matchbox 72 and the coils 66. The afterburner assembly 60 including these components is energized using power source 70 at the beginning of the plasma ashing process. The reactant containing gas admixture passing through the coupled RF field produces a plasma discharge that effectively and efficiently combusts organic matter passing therethrough. Preferably, the afterburner assembly 60 is configured to simultaneously operate during plasma ashing processing of a semiconductor workpiece 11 seated on the wafer pedestal 30 in the process chamber 16.

Optionally, the portion of the exhaust conduit 50 intermediate the process chamber opening 40 and the afterburner assembly 60 is heated during processing so as to prevent hydrocarbon buildup on surfaces between the process chamber 16 and the afterburner assembly 60, or other effluent management system (not shown).

Additionally, the exhaust conduit 50 may include an optical detection system 80. The optical detection system 80 optically detects emission peaks from the plasma generated by the afterburner assembly that have particular wavelength ranges that correspond to the reaction byproducts (or reactants) of the reactions between the plasma and the photoresist. The technique relies on detecting the change in the emission intensities of characteristic optical radiation from the reactants and/or byproducts in the plasma, wherein the magnitude of change can signal an end of the plasma ashing process. Excited atoms or molecules in the plasma emit light when electrons relax from a higher energy state to a lower energy state. Atoms and molecules of different chemical compounds emit a series of unique spectral lines. The emission intensity for each chemical compound within the plasma depends on the relative concentration of the chemical compound in the plasma. The optical detection system 80 generally includes a collection optics 82 arranged outside the exhaust conduit 50 to collect the emission spectra thus passed. Since the exhaust conduit 50 is preferably fabricated from an optically transparent material such as quartz or sapphire, an optical port or window is not necessary. In the event that an optically non-transparent dielectric material is employed for the fabrication of the exhaust conduit, an optical port of quartz or sapphire may be formed in the exhaust conduit. A spectrometer or monochromator 84 is arranged to receive light from the collection optics 82.

Plasma apparatuses including the afterburner assembly 60 and optical detection system 80 can be configured with a control system that shuts off the plasma flow in the afterburner assembly 60 and/or the plasma source 14, 114 when it measures spectral line intensities that exceed (or drop below depending on how the apparatus is configured) a predetermined value or range or a combination of predetermined values/ranges for different spectral lines. For example, upon determining ashing endpoint has occurred from data collected by the optical detector 82 in the exhaust conduit, the plasma ashing process can be immediately discontinued via a feedback loop.

The particular optical detector is not intended to be limited and it is well within the skill of those in the art to choose a suitable optical detector. An exemplary optical detector is described in U.S. patent application Ser. No. 10/249,962 (Publication No. US2004-023812A1), filed on May 22, 2003 and titled, Plasma Apparatus, Gas Distribution Assembly for a Plasma Apparatus, and Processes Therewith, incorporated herein by reference in its entirety. Optionally, a residual gas analyzer may be included in order to obtain relevant information on reactants, byproducts, and/or end of process.

For plasma sources wherein the substantially non-oxidizing plasma exposes a dielectric material such as quartz, alumina, zirconia, or other ceramic material, degradation and/or devitrification of the dielectric material can occur. To prevent this deleterious effect, the dielectric material must be cooled sufficiently to prevent the substantially non-oxidizing plasma from causing the degradation and/or devitrification. It has been found that if the substantially non-oxidizing plasma exposed dielectric surfaces are cooled to a temperature of 700° C. or lower degradation and/or devitrification is substantially reduced.

In operation, a semiconductor wafer (e.g., workpiece 11 in FIG. 1 or workpiece 124 shown in FIG. 4) with photoresist, ion implanted photoresist residues and/or post etch residues thereon (and an oxidation sensitive material such as a high-k dielectric, metal gate or the like) is placed into the process chamber 16 on the wafer pedestal. The workpiece is preferably heated such by infrared lamps 33 as shown in FIG. 1 or a thermally heated chuck to accelerate the reaction of the photoresist and/or post etch residues with the plasma. The pressure within the process chamber 16 is then reduced. Preferably, the pressure within the process chamber 16 is maintained between about 0.1 torr to about 5 torr. An excitable substantially non-oxidizing plasma gas mixture is then fed into the plasma-generating component 14. Depending on the application, the charged particles may be selectively removed before the plasma enters the process chamber 16. The excited or energetic atoms of the gas are then fed into the process chamber 15 and uniformly expose the workpiece where, for example, atomic hydrogen species react with the photoresist and/or post etch residues, which causes removal of the photoresist material and also forms somewhat volatile byproducts. The photoresist material and volatile byproducts are continuously swept away from the workpiece surface to the exhaust conduit assembly 18.

Simultaneously with plasma ashing, a reactant gas is fed into the afterburner assembly 60 in the exhaust conduit 50, which is downstream from the process chamber 16. None of the injected reactant gas enters the process chamber 16 due to the “plug-flow” condition imposed by the much larger process gas flow rate from the process chamber into the exhaust conduit 50. The afterburner assembly 60 is then energized to form high-density plasma within the exhaust conduit 50. Once the removal of photoresist and/or residues is complete, this endpoint being generated optically either in the process chamber 16 itself and/or within the exhaust conduit 50 downstream from the afterburner assembly 60, a signal is then sent to a control unit (not shown) and the various plasma sources (14 or 144, and 60) can be turned off. The vacuum is then released and the processed workpieces may be removed from the process chamber. An optional water rinse can be used to remove any remaining residue on the stripped wafer.

Any suitable semiconductor workpiece can be processed by the substantially non-oxidizing plasma generated by the apparatuses 10, 100. In some embodiments, the semiconductor workpiece includes an oxidation sensitive material such as a high-k dielectric or a metal gate. High-k dielectric materials are hereinafter defined as a metal oxide, a metal nitride, or a combination of metal oxides or metal nitrides suitable for use in the manufacture of integrated circuits or the like having a dielectric constant greater than about 4, with a dielectric constant greater than about 10 more preferred. Examples of high-k dielectric materials include HfO₂, HfSiO₄, Al2O₃, HfAlO₃, Gd₂O₃, LaAlO₃, Sc2O₃, Y₂O₃, Dy₂O₃, GdScO₃, DyScO₃, ZrO₂, BaZrO₃, Ta₂O₅, Nb₂O₅, HfTia₄, TiO₂, SrTiO₃ or combinations thereof. The oxygen sensitive metal gate materials include: Ru, Mo, Ti, Ta, W, TiN, TaN, WN, HfN, Mo₂N, HfSiN, TaSiN, MoSiN, TiSiN, HfSiₓ, TaSiₓ, NiSiₓ, and MoSiₓ or combinations thereof, where x is an integer from 1 to 8.

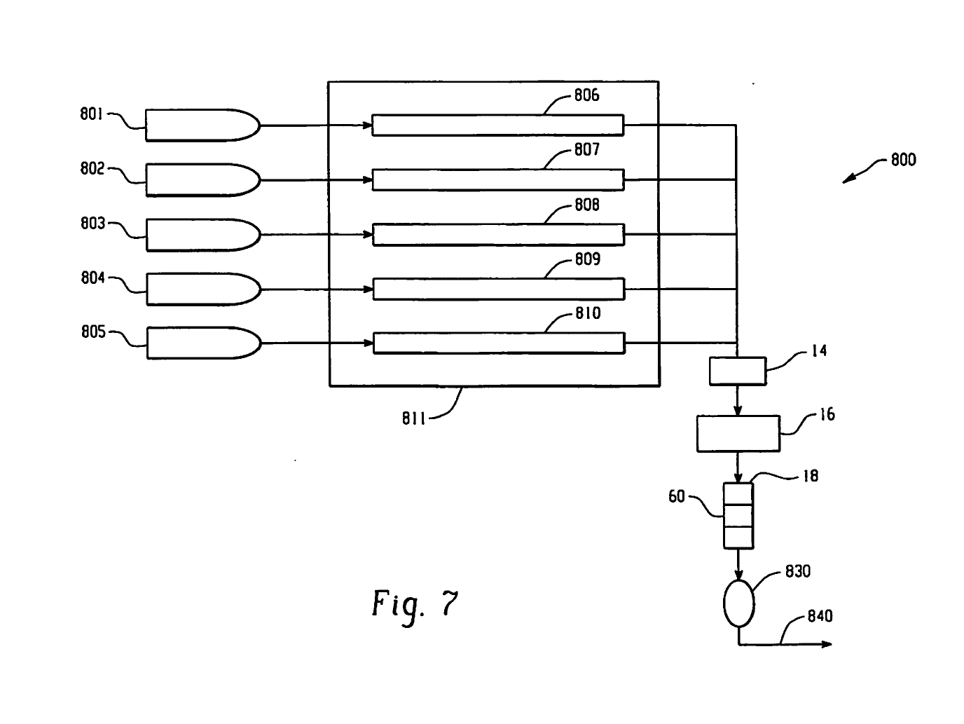

Referring now to FIG. 7, a gas flow configuration 800 for the plasma apparatus 10, 100 is schematically represented. The gas flow configuration 800 includes a plurality of gases 801, 802, 803, 804, 805 fluidly controlled through corresponding mass flow controllers 806, 807, 809, 809, 810 located in an exhausted gas box enclosure 811. More or less gases and mass flow controllers can be Employed as may be desired for different applications. The gases include at least a substantially non-oxidizing gas source 801 such as one of the hydrogen bearing gases discussed above. Additionally, the substantially non-oxidizing gas 801 may be combined with one or more gases to provide additional advantages. For example, the substantially non-oxidizing gas 801 can be combined with a nitrogen bearing gas 802 so as to mitigate hydrogen reduction of metal nitrides or metal silicides and/or a gas 803 to mitigate CuH production, and/or a halogen bearing gas 804, and/or a diluent gas 805. The particular combinations are not intended to be limited. Each of the gases is connected to individual mass flow controllers and mixed with the substantially non-oxidizing process gas prior to entering the plasma generating component 12. The plasma source 12 can be fluidly connected to a heated process chamber 16 that is fluidly connected to an exhaust assembly 18 that includes an afterburner abatement system 60. A reactant gas 820 (e.g., an oxidizer) is injected into the afterburner assembly 60 and is used to convert the hydrocarbon effluent from the process chamber 16 into volatile compounds. The effluent of the afterburner assembly 60 is directed into vacuum pump 830, which is fluidly connected to an exhaust 840.

The following examples are presented for illustrative purposes only, and are not intended to limit the scope of the disclosure.

### Example 1

In this example, bare silicon wafers were exposed to plasma generated from forming gas in a RapidStrip320 plasma ashing tool commercially available from Axcelis Technologies, Inc., Beverly, Mass. Different processing chamber configurations of different materials were employed. Copper metal contamination levels of the bare silicon wafers was determined after plasma processing by vapor phase decomposition with inductively coupled plasma mass spectrometer analysis (VDP ICP-MS). The plasma chemistry was formed by flowing forming gas (5% Hydrogen in Nitrogen) at 7 standard liters per minute (slm) into the plasma ashing tool at a pressure of 1 Torr, a wafer temperature of 275° C., and a power setting of 3500 Watts.

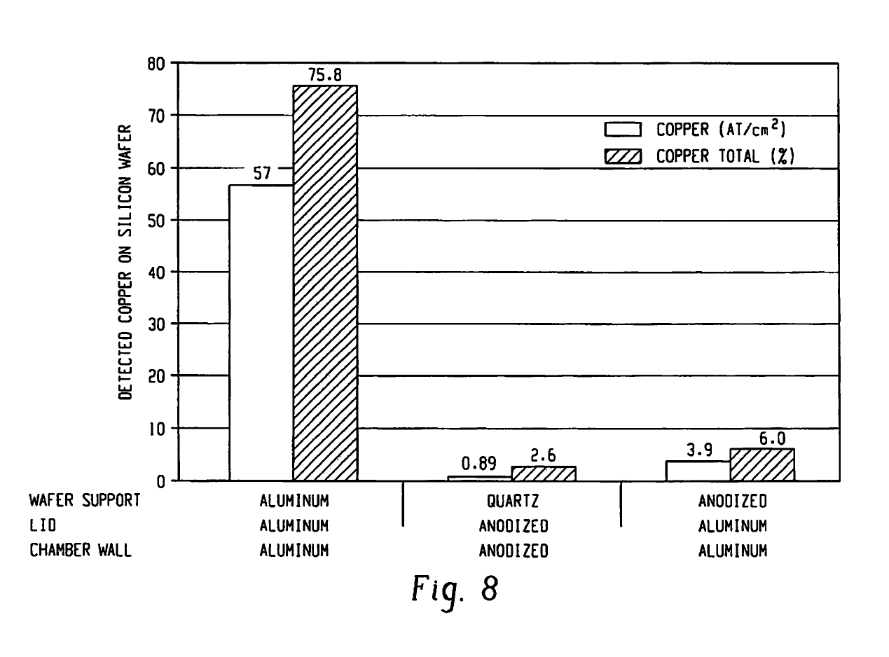

FIG. 8 graphically illustrates the results for both the absolute copper amount (atms/cm²) and the relative copper amount (detected copper atoms/total atoms of 11 probed metals in %). The process chamber configured with a chuck formed of an aluminum alloy demonstrated the highest amounts of copper contamination. In contrast, copper contamination was minimized by use of a chuck having an anodized surface. The process chamber configuration with the lowest levels of detected copper levels (comparable to a control silicon wafer that had not been processed) had all anodized or quartz surfaces with no exposed aluminum alloy surface.

### Example 2

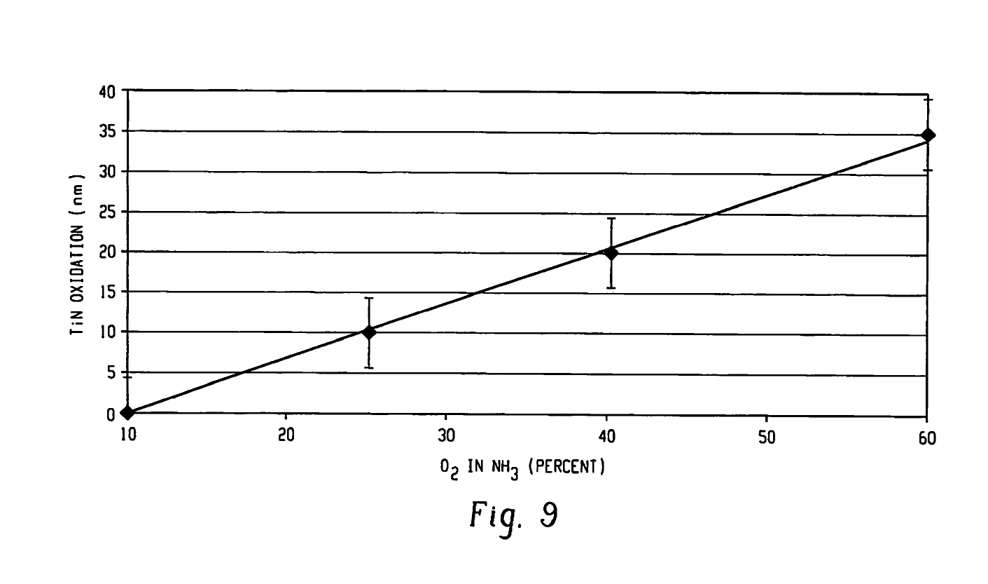

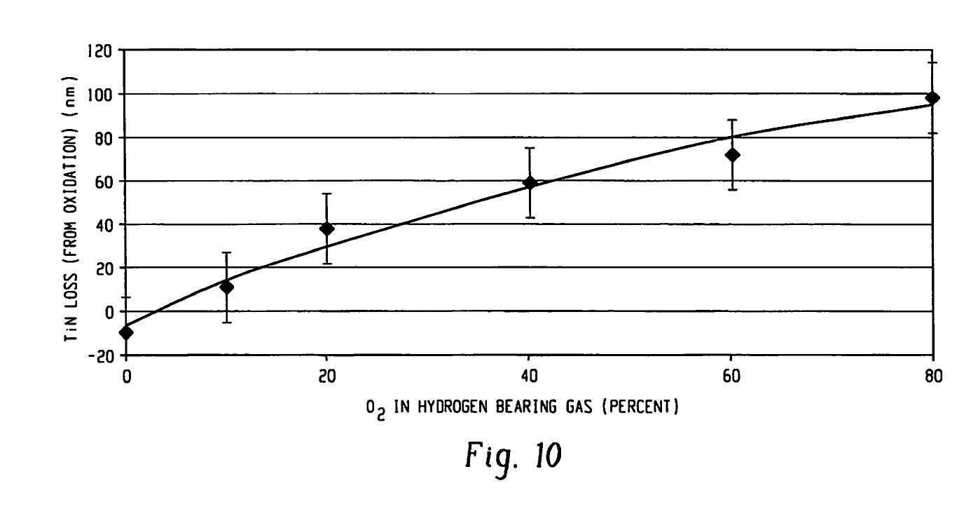

In this example, a substrate having a TiN coating deposited thereon was exposed to plasmas formed from a gas mixture containing varying amounts of oxygen and NH₃ and a gas mixture that contained varying amounts of oxygen and a 5% by volume hydrogen gas/helium gas mixture without any nitrogen present in the mixture. The results are shown in FIGS. 9 and 10.

FIG. 9 graphically illustrates the amount of oxidation of a TiN material exposed to a plasma gas mixture of NH₃ and O₂ for 3 minutes, with chuck temperature at 240° C. For O₂ concentrations of <about 25%, the results showed that TiN oxidation is ≦0.1 nm for the exposure conditions. Thus, these results demonstrate the plasma was substantially non-oxidizing when the TiN material was exposed to plasma generated from a gas mixture containing less than 25% by volume.

FIG. 10 graphically illustrates the amount of TiN loss as a result of oxidation as a function of the amount of oxygen contained in the mixture of O₂ and the hydrogen gas mixture (5% by volume hydrogen/helium gas mixture), wherein the TiN was exposed to plasma generated from the plasma gas mixture. Without the presence of nitrogen in the gas mixture for forming the plasma, the exposed TiN was reduced to Ti as represented by the negative oxidation loss when the plasma gas mixture contained less than a few percent of oxygen to no oxygen. In FIG. 9, this behavior was not observed and is believed to be due to the presence of nitrogen in the NH₃ gas.

While the disclosure has been described with reference to a preferred embodiment, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. A plasma treatment device for treating a substrate, comprising:
a gas inlet in fluid communication with a plasma generating component and configured to receive a substantially non-oxidizing gas source,
wherein the plasma generating component is configured to generate plasma from the substantially non-oxidizing gas source during operation of the plasma treatment device;
a process chamber in fluid communication with the plasma generating component and configured to receive the plasma, wherein the process chamber includes walls,
wherein the walls include a top wall, a bottom wall, and sidewalls that extend from the bottom wall to the top wall, and
wherein the walls are formed of a material containing less than 0.15% copper by weight;
an exhaust conduit fluidly connected to the process chamber; and
a heater configured to heat the walls of the process chamber and the exhaust conduit to a surface temperature greater than 100° C. during operation of the plasma treatment device to prevent particulate buildup on the walls during operation.

2. The plasma treatment device of claim 1, wherein the process chamber material is an aluminum metal alloy.

3. The plasma treatment device of claim 1, wherein the plasma generating component is a wide area plasma source powered by radio frequency power, microwave power or a combination thereof.

4. The plasma treatment device of claim 1, wherein the plasma generating component is a narrow area plasma source, wherein the process chamber includes a domed top wall and a single baffle plate configured to distribute reactive plasma species in the plasma such that a path length of the reactive plasma species to an underlying substrate contained therein is about the same to all points on the underlying substrate.

5. The plasma treatment device of claim 4, wherein the single baffle plate includes an inner region and an outer region, wherein an aperture density is greater in the outer region than the inner region, and wherein the inner region includes a central substantially-apertureless portion for introducing the plasma reactive species into the process chamber, wherein the substantially-apertureless portion includes a single aperture centrally located in the single baffle plate.

6. The plasma treatment device of claim 5, wherein the central apertureless portion has a diameter about equal to an opening diameter of the narrow area plasma generating component.

7. The plasma treatment device of claim 1, wherein the process chamber further comprises a sleeve formed of a non-copper containing material configured to contour interior surfaces of the process chamber exposed to the during operation of the plasma treatment device.

8. The plasma treatment device of claim 7, wherein the process chamber comprise a top wall, a bottom wall, sidewalls extending from the bottom wall to the top wall, the baffle plate, and combinations thereof.

9. The plasma treatment device of claim 1, further comprising an afterburner assembly coupled to the exhaust conduit, wherein the exhaust conduit comprises a gas port intermediate to the process chamber and the afterburner assembly.

10. The plasma treatment device of claim 1, wherein the plasma generating component comprises a wide area plasma source comprising an antenna array comprising a plurality of single antenna conductors coupled together and in electrical communication with a power source, wherein the antenna array is parallel to an underlying substrate and is configured to generate substantially non-oxidizing plasma reactive species from the non-oxidizing gas source.

11. The plasma treatment device of claim 1, wherein exterior walls of the process chamber are thermally insulated.

12. The plasma treatment device of claim 1, wherein the substantially non-oxidizing gas source comprises a hydrogen containing gas.

13. The plasma treatment device of claim 1, wherein the substantially non-oxidizing gas source comprises at least one gas in fluid communication with a mass flow controller, wherein at least one gas is selected from the group consisting of H₂, NH₃, N₂H₄, H₂S, CH₄, C₂H₆, C₃H₈, HF, H₂O, HCl, HBr, HCN, CO, N₂O, and combinations thereof.

14. The plasma treatment device of claim 1, wherein the substantially non-oxidizing gas source comprises a plurality of gases that form the plasma, wherein each one of the plurality of gases is in fluid communication with a mass flow controller.

15. The plasma treatment device of claim 14, wherein the plurality of gases comprises a nitrogen bearing gas selected from the group consisting of N₂, NO, N₂O, NH₃, HCN, and combinations thereof.

16. The plasma treatment device of claim 14, wherein least one of the plurality of gases is in an amount effective to inhibit formation of copper hydride during the plasma process, wherein the at least one gas is selected from the group consisting of O₂, N₂O, NH₃, CH₄, CF₄, C₂F₆, SF₆, H₂S, Cl₂, F₂, CHF₃, CH₂F₂, CH₃F, HF, HCl, CO, CO₂, HCN, C₂H₆, C₃H₈, and mixtures thereof.

17. The plasma treatment device of claim 14, wherein the plurality of gases further comprises an inert gas, wherein the inert gas is selected from the group consisting of He, N₂, Ne, Ar, and mixtures thereof.

18. The plasma treatment device of claim 1, further comprising an optical detector coupled to the process chamber and configured to monitor an optical emission spectrum associated with emission signals from oxygen and/or oxygen containing molecules; and a feedback loop configured to provide a warning signal or process termination signal when an intensity of the optical emission spectrum differs from a predetermined value or range.

19. The plasma treatment device of claim 18, wherein the optical emission spectrum associated with the emission signals from the oxygen and/or the oxygen containing molecules is a spectral line selected from the group consisting of 293 nm, 303 nm, 307 nm, 314 nm, 484 nm, 520 nm, 777 nm, 845 nm, 927 nm, and mixtures thereof.

20. The plasma treatment device of claim 1, further comprising an active temperature control system coupled to the process chamber, wherein the active temperature control system regulates a temperature of interior surfaces that define the process chamber.

21. A plasma treatment device for treating a substrate, comprising:
a gas inlet in fluid communication with a plasma generating component and configured to receive a substantially non-oxidizing gas source,
wherein the plasma generating component is configured to generate plasma from the substantially non-oxidizing gas source during operation of the plasma treatment device;
a process chamber in fluid communication with the plasma generating component and configured to receive the plasma, wherein the process chamber
includes walls,
wherein the walls include a top wall, a bottom wall, and sidewalls that extend from the bottom wall to the top wall, and
wherein the walls are formed of a material containing less than 0.15% copper by weight and magnesium greater than 4% by weight;
an exhaust conduit fluidly connected to the process chamber;
an afterburner assembly coupled to the exhaust conduit, wherein the exhaust conduit comprises a gas port intermediate to the process chamber and the afterburner assembly; and
a heater configured to heat the walls of the process chamber and a portion of the exhaust conduit between the process chamber and the afterburner to a surface temperature greater than 100° C. during operation of the plasma treatment device to prevent particulate buildup on the walls during operation.

22. A plasma treatment device for treating a substrate, comprising:
a gas inlet in fluid communication with a plasma generating component and configured to receive a substantially non-oxidizing gas source,
wherein the plasma generating component is configured to generate plasma from the substantially non-oxidizing gas source during operation of the plasma treatment device;
a process chamber in fluid communication with the plasma generating component and configured to receive the plasma,
wherein the process chamber includes walls, wherein the walls are formed of an aluminum alloy;
an exhaust conduit fluidly connected to the process chamber;
an afterburner assembly coupled to the exhaust conduit, wherein the exhaust conduit comprises a gas port intermediate to the process chamber and the afterburner assembly; and
a heater configured to heat the walls of the process chamber and a portion of the exhaust conduit between the process chamber and the afterburner to a surface temperature greater than 100° C. during operation of the plasma treatment device.
